(19) United States
(12) Patent Application Publication
(10) Pub. No.: US 2006/0228975 A1
(43) Pub. Date: Oct. 12, 2006

(54) Liquid droplet ejection apparatus, method for forming structure, and method for manufacturing electro-optic device

(76) Inventor: Hirotsuna Miura, Suwa-shi (JP)

Correspondence Address: HARNESS, DICKEY & PIERCE, P.L.C., P.O. BOX 828, BLOOMFIELD HILLS, MI, 48303, US

(21) Appl. No.: 11/390,484

(22) Filed: Mar. 27, 2006

(30) Foreign Application Priority Data
Mar. 29, 2005 (JP) 2005-096385

(51) Int. Cl. H01J 9/24

(52) U.S. Cl. 445/24; 347/121

(57) ABSTRACT

A liquid droplet ejection apparatus includes a liquid droplet ejecting portion that ejects a liquid droplet containing a structure forming material onto a structure forming area defined on a target; and an energy beam radiating portion that radiates an energy beam having a predetermined intensity onto at least a portion of the droplet on the structure forming area. The predetermined intensity is set to a value that permits the droplet on the structure forming area to spread wet on the structure forming area. According to the liquid droplet ejection apparatus, a structure having a precisely controlled shape is obtained.

### CROSS-REFERENCE TO RELATED APPLICATIONS

This application is based upon and claims the benefit of priority from prior Japanese Patent Application No. 2005-096385, filed on Mar. 29, 2005, the entire contents of which are incorporated herein by reference.

### BACKGROND

The present invention relates to a liquid droplet ejection apparatus, a method for forming a structure, and a method for manufacturing an electro-optic device.

Typically, a color filter substrate of a liquid crystal display is provided with a dot pattern consisting of a plurality of color films each having a dot like shape. The color films are provided through a liquid phase process. More specifically, in the liquid phase process, liquid containing color film forming material is ejected onto color film forming sections, each of which is encompassed by a wall. The liquid is then dried in the color film forming sections so as to form the color films.

As described in Japanese Laid-Open Patent Publication No. 2002-189120, an inkjet method may be used as the liquid phase process. Specifically, according to the inkjet method, liquid is ejected onto each of color film forming sections as a microdroplet. The microdroplet is then dried to provide a color film.

The inkjet method reduces consumption of the liquid compared to other liquid phase processes including a spin coat method and a dispenser method. Further, the position of each color film is adjusted with improved accuracy. However, in the inkjet method, there are cases in which microdroplets do not spread sufficiently for entirely covering the corresponding color film forming sections, due to surface tension of the microdroplets or the surface conditions of the color film forming sections. In these cases, the obtained color films cannot entirely cover the corresponding color film forming sections.

This problem may be solved by subjecting each of the color film forming sections to surface treatment (for example, lyophilic property treatment that provides a lyophilic property to each color film forming section with respect to the microdroplets) As an alternative solution, the surface tension of each microdroplet may be decreased by employing a different material for forming the microdroplet. However, neither of these solutions is sufficiently effective for allowing the microdroplets to spread to entirely cover the corresponding color film forming sections.

### SUMMARY

An advantage of some aspect of the invention is to provide a liquid droplet ejection apparatus and a method for forming a structure that form a structure having a precisely controlled shape and to provide a method for manufacturing an electro-optic device that has a color film or a light emission element having a precisely controlled shape.

To achieve the foregoing and other objectives and in accordance with the purpose of the present invention, according to a first aspect of the invention, a liquid droplet ejection apparatus is provided. The liquid droplet ejection apparatus includes: a liquid droplet ejecting portion that ejects a liquid droplet containing a structure forming material onto a structure forming area defined on a target; and an energy beam radiating portion that radiates an energy beam having a predetermined intensity onto at least a portion of the droplet on the structure forming area. The predetermined intensity is set to a value that permits the droplet on the structure forming area to spread wet on the structure forming area.

According to a second aspect of the invention, a method for forming a prescribed structure on a target is provided. The method includes: ejecting a liquid containing a structure forming material onto the target, drying the liquid on the target to form the structure, and radiating an energy beam having a predetermined intensity onto at least a portion of the liquid on the target before or when drying the liquid on the target. The predetermined intensity is set to a value that permits the liquid on the target to spread wet on the target.

According to a third aspect of the invention, a method for manufacturing an electro-optic device is provided. The electro-optic device includes a substrate in which a color film is provided. The method includes forming the color film on the substrate by the method for forming a prescribed structure on a target.

According to a fourth aspect of the invention, another method for manufacturing an electro-optic device is provided. The electro-optic device includes a substrate in which a light emission element is provided. The method includes forming the light emission element on the substrate by the method for forming a prescribed structure on a target.

Other aspects and advantages of the invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a perspective view showing a liquid crystal display according to a first embodiment of the present invention;

FIG. 2 is a perspective view showing a color filter substrate of the liquid crystal display of FIG. 1;

FIG. 3 is a cross-sectional view along the line 3-3 of FIG. 2;

FIG. 4 is a perspective view schematically showing a liquid droplet ejection apparatus according to the first embodiment;

FIG. 5 is a perspective view schematically showing a liquid droplet ejection head of the liquid droplet ejection apparatus of FIG. 4;

FIG. 6 is a cross-sectional view for explaining the liquid droplet ejection head of FIG. 5;

FIG. 7A is a view illustrating the shape of a beam spot;

FIG. 7B is a graph representing the radiation intensity of the beam spot;

FIGS. 8A, 8B, and 8C are views showing the beam spot of FIG. 7A with respect to a color film forming area;

FIG. 9 is a block circuit diagram showing the electric configuration of the liquid droplet ejection apparatus of FIG. 4;

FIG. 10 is a timing chart representing operational timings of a piezoelectric element and those of a semiconductor laser;

FIGS. 11 and 12 are cross-sectional views showing a main portion of a liquid droplet ejection head according to a second embodiment of the present invention;

FIGS. 13A, 13B, and 13C are views showing a beam spot according to the second embodiment with respect to a color film forming area;

FIG. 14 is a block circuit diagram showing the electric configuration of a liquid droplet ejection apparatus having the liquid droplet ejection head of FIGS. 11 and 12;

FIG. 15 is a timing chart representing operational timings of a piezoelectric element and those of a semiconductor laser according to the second embodiment; and

FIGS. 16A, 16B, and 16C are views showing a beam spot according to a third embodiment of the present invention relative to a color film forming area.

### DESCRIPTION OF EXEMPLARY EMBODIMENTS

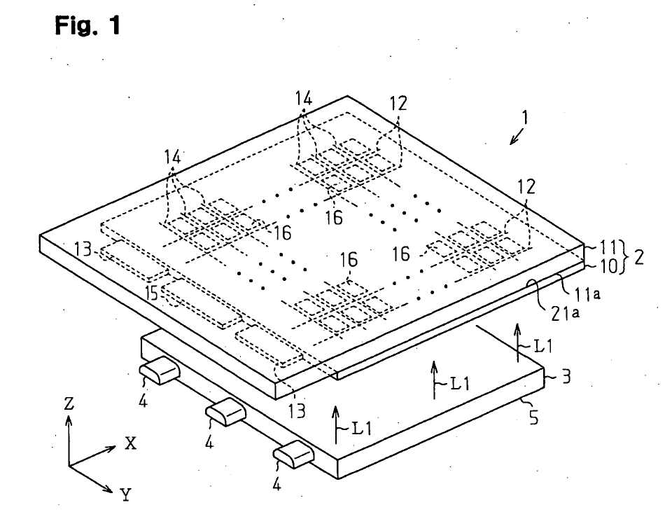

A first embodiment of the present invention will now be described with reference to FIGS. 1 to 10.

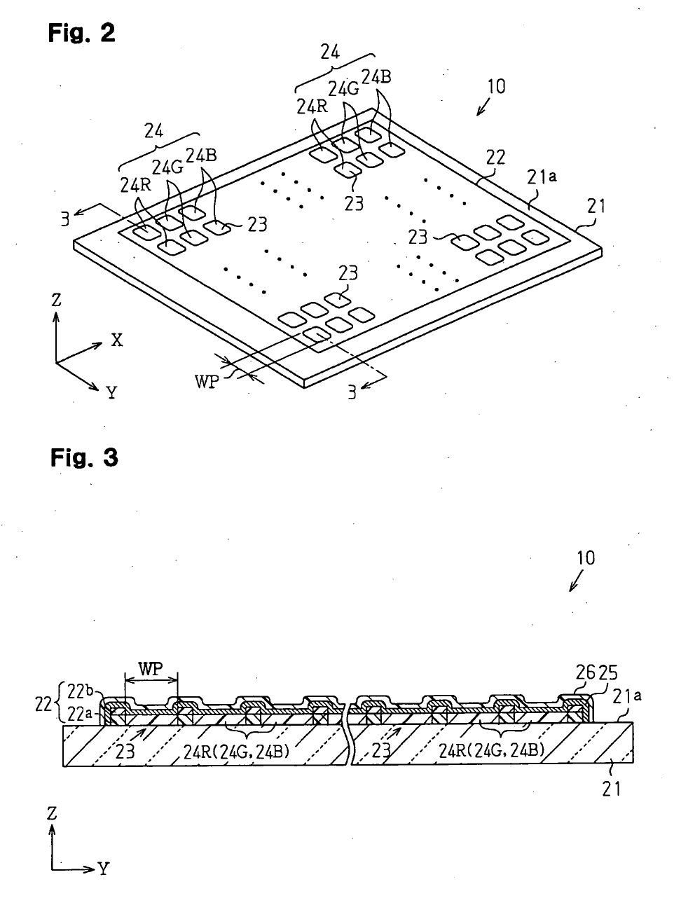

First, a liquid crystal display 1, or an electro-optic device according to the first embodiment, will be explained. FIG. 1 is a perspective view showing the liquid crystal display 1, FIG. 2 is a perspective view showing a color filter substrate 10 of the liquid crystal display 1, and FIG. 3 is a cross-sectional view showing the color filter substrate 10.

As shown in FIG. 1, the liquid crystal display 1 includes a liquid crystal panel 2 and an illumination device 3 that illuminates an area light L1 onto the liquid crystal panel 2.

The illumination device 3 has light sources 4, which are, for example, LEDs, and a light guide 5. The light guide 5 produces the area light L1, which is illuminated onto the liquid crystal panel 2, from the light emitted by the light sources 4. The liquid crystal panel 2 has a color filter substrate 10 and an element substrate 11 that are bonded together. Non-illustrated liquid crystal molecules are sealed between the color filter substrate 10 and the element substrate 11. The position of the liquid crystal panel 2 is determined relative to the position of the illumination device 3 in such a manner that the color filter substrate 10 is located closer to the illumination device 3 than the element substrate 11.

The element substrate 11 is formed by a rectangular non-alkaline glass and includes an element forming surface 11a, which is a surface of the element substrate 11 facing the illumination device 3 (the color filter substrate 10). A plurality of scanning lines 12 are provided and equally spaced on the element forming surface 11a, extending in direction X. The scanning lines 12 are electrically connected to a scanning line driver circuit 13 arranged at an end of the element substrate 11. In correspondence with a scanning control signal of a control circuit (not shown), the scanning line driver circuit 13 generates a scanning signal for driving selected ones of the scanning lines 12 at predetermined timings.

A plurality of data lines 14 are formed and equally spaced on the element forming surface 11a, extending in direction Y perpendicular to each scanning line 12. The data lines 14 are electrically connected to a data line driver circuit 15, which is formed at the end of the element substrate 11. In correspondence with display data sent from a non-illustrated external device, the data line driver circuit 15 produces a data signal and outputs the data signal to a corresponding one of the data lines 14 at a predetermined timing.

A plurality of pixel areas 16 are formed on the element forming surface 11a. The pixel areas 16 are aligned in a matrix-like shape of “i” rows by “j” columns. Each of the pixel areas 16 is encompassed by an adjacent pair of the scanning lines 12 and an adjacent pair of the data lines 14 and is connected to the corresponding scanning line 12 and the associated data line 14. A non-illustrated control element formed by, for example, a TFT and a pixel electrode are formed in each pixel area 16. The pixel electrode is formed by a transparent conductive film formed of, for example, ITO. In other words, the liquid crystal display 1 is an-active-matrix-type liquid crystal display that includes the control element such as a TFT.

A non-illustrated alignment film is provided on the scanning lines 12, the data lines 14, and the pixel areas 16 to cover the element forming surface 11a entirely. The alignment film is subjected to alignment treatment such as rubbing treatment. The alignment film thus orientates the liquid crystal molecules in the vicinity of the alignment film in a certain direction.

As shown in FIG. 2, the color filter substrate 10 includes a rectangular transparent glass substrate 21 formed of non-alkaline glass.

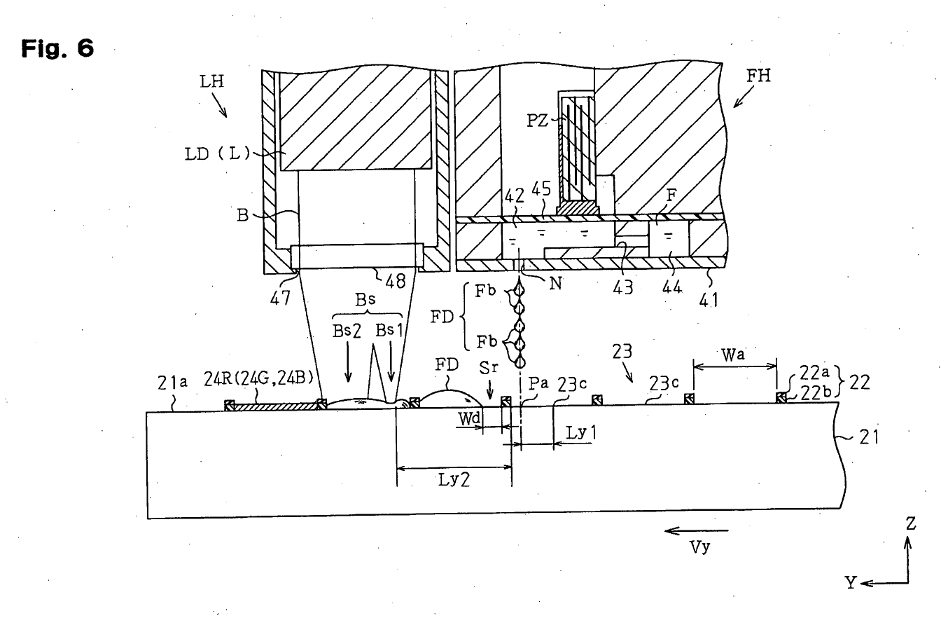

As shown in FIG. 3, the color filter substrate 10 includes a color film forming surface 21a, which is a surface of the color filter substrate 10 that faces the element substrate 11. A light shielding layer 22a is provided on the color film forming surface 21a. The light shielding layer 22a is formed of resin containing light shielding material such as chrome and carbon black. The light shielding layer 22a has a grid-like shape corresponding to the scanning lines 12 and the data lines 14. A liquid repelling layer 22b is defined on the light shielding layer 22a. The liquid repelling layer 22b is a resin layer formed of fluorinated resin that repels liquid droplets FD (see FIG. 6), which will be later described. The liquid repelling layer 22b prevents the droplets FD from protruding from corresponding structure forming areas. In the first embodiment, the structure forming areas are color film forming areas 23, which also will be explained later.

Referring to FIG. 2, a grid-like wall 22 is formed on a substantially entire portion of the color film forming surface 21a by the light shielding layer 22a and the liquid repelling layer 22b. The color film forming areas 23, which are portions of the color film forming surface 21a that are encompassed by the corresponding portions of the wall 22, are aligned in a matrix-like shape of “i” rows by “j” columns. Each of the color film forming areas 23 is opposed to the corresponding one of the pixel areas 16. In the first embodiment, each of the color film forming areas 23 has a substantially square shape and each side of the color film forming area 23 is 100 μm long (a pixel width WP of each color film forming area 23 is 100 μm).

In this embodiment, the rows of the color film forming areas 23 are sequentially numbered in a direction opposite to direction Y as a first row to an “i”th row.

With reference to FIGS. 2 and 3, a color film 24, which is a structure, having a dot like shape is formed in each of the color film forming areas 23. The color films 24 are arranged to form a predetermined dot pattern. The color films 24 include red films 24R, green films 24G, and blue films 24B, which are provided in a manner alternating in this order along direction X of FIG. 2.

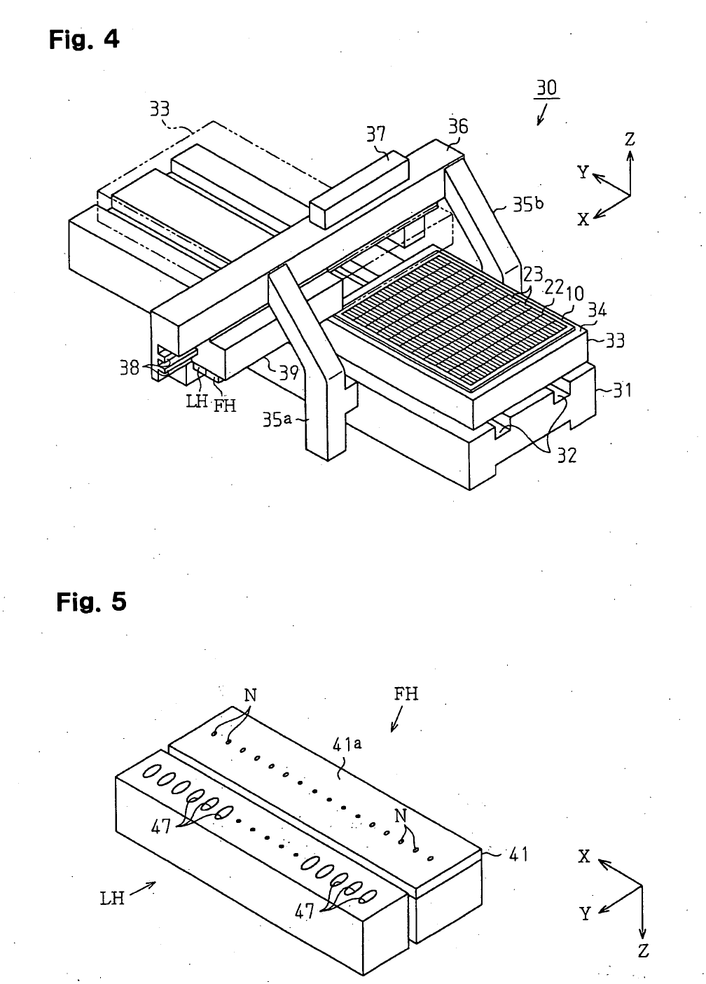

The color films 24 are provided using a liquid droplet ejection apparatus 30 (see FIG. 4), which will be described later. Specifically, microdroplets Fb (see FIG. 6) containing material for forming the color films 24, or structure forming material, are ejected onto the corresponding color film forming areas 23 through ejection nozzle holes N (see FIG. 5). The microdroplets Fo are then received-by and dried on the color film forming surface 21a. The color films 24 are thus provided.

Referring to FIG. 3, an opposing electrode 25 is formed on the color films 24R, 24G, 24B. The opposing electrode 25 opposes the pixel electrodes of the element substrate 11. A predetermined common potential is provided to the opposing electrode 25. An alignment film 26 is defined on the opposing electrode 25 and orientates the liquid crystal molecules in the vicinity of the opposing electrode 25 in a certain direction.

In accordance with line-sequential scanning, the scanning line driver circuit 13 sequentially drives the scanning lines 12 one by one. This sequentially activates the control elements of the pixel areas 16. Activation of each control element is maintained only for the time corresponding to the time in which the associated scanning line 12 is activated. In correspondence with the activated control element, the data signal generated by the data line driver circuit 15 is sent to the associated pixel electrode through the corresponding data line 14 and the control element. The orientation of the liquid crystal molecules is thus held in a state in which the light L1 from the illumination device 3 is modulated in correspondence with the difference between the potential of the pixel electrode of the element substrate 11 and the potential of the opposing electrode 25 of the color filter substrate 10. Accordingly, by selectively passing the modulated light L1 through a non-illustrated deflection plate, the liquid crystal panel 2 displays a desired full-color image through the color filter substrate 10.

The liquid droplet ejection apparatus 30 used for forming the color films 24 will hereafter be described. FIG. 4 is a perspective view showing the liquid droplet ejection apparatus 30.

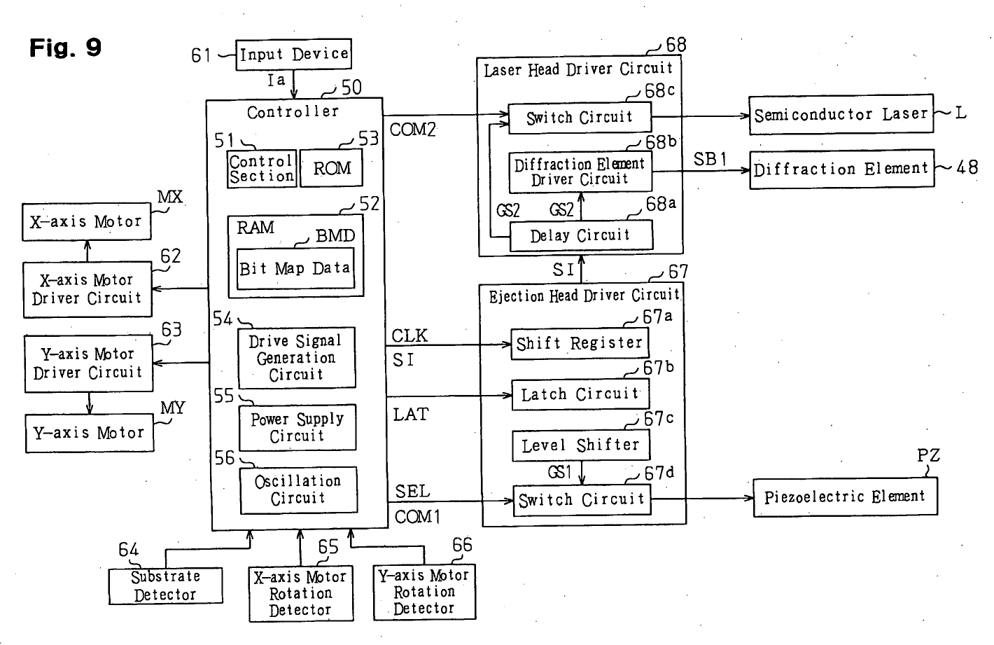

As shown in FIG. 4, the liquid droplet ejection apparatus 30 includes a parallelepiped base 31. The base 31 is provided in such a manner that the longitudinal direction of the base 31 extends in direction Y with the color filter substrate 10 mounted on a substrate stage 33, which will be described later. A pair of guide grooves 32 are defined in the upper surface of the base 31 and extend throughout the base 31 in direction Y. The substrate stage 33 having a non-illustrated linear movement mechanism corresponding to the guide grooves 32 is secured to the upper surface of the base 31. The linear movement mechanism of the substrate stage 33 is a threaded type linear movement mechanism having, for example, a threaded shaft (a drive shaft) extending along the guide grooves 32 in direction Y and a ball nut that is engaged with the threaded shaft. The drive shaft of the linear movement mechanism is connected to a y-axis motor MY (see FIG. 9), which is a stepping motor. The y-axis motor MY rotates in a forward or reverse direction in response to a drive signal corresponding to a predetermined number of steps. This advances or retreats (moves) the substrate stage 33 at a predetermined transport speed Vy along direction Y by an amount corresponding to the number of steps.

In the first embodiment, referring to FIG. 4, when the base 31 is located at a foremost position in direction Y (as indicated by the solid lines in FIG. 4), it is defined that the base 31 is arranged at a proceed position. When the base 31 is located at a rearmost position in direction Y (as indicated by the double-dotted broken lines in FIG. 4), it is defined that the base 31 is arranged at a return position.

A suction type chuck mechanism (not shown) is provided on a mounting surface 34, which is the upper surface of the substrate stage 33. When the color filter substrate 10 is mounted on the mounting surface 34 with the surface having the color film forming areas 23 facing upward, the color filter substrate 10 is positioned with respect to the mounting surface 34. The substrate stage 33 is then advanced at the transport speed Vy in direction Y in such a manner that the color film forming areas 23 move at the transport speed Vy in direction Y. In the first embodiment, the transport speed Vy is set to 200 nm/s. However, the transport speed Vy is not restricted to this value.

A pair of supports 35a, 35b are provided at opposing sides of the base 31 in direction X. The supports 35a, 35b support a guide member 36 extending in direction X. The longitudinal dimension of the guide member 36 is greater than the dimension of the substrate stage 33 in direction X. An end of the guide member 36 is projected beyond the support 35a. A non-illustrated maintenance unit is arranged immediately below the projected end of the guide member 36. The maintenance unit wipes off a nozzle surface 41a (see FIG. 5) of a liquid droplet ejection head FH, which will be explained later, thus cleansing the nozzle surface 41a.

A tank 37 is located on the guide member 36 and retains color film forming liquids F (see FIG. 6) of the three colors. The color film forming liquid F of each of the colors is prepared by dispersing color film forming material (which is, for example, organic pigment) of the corresponding color in dispersion medium. The tank supplies color film forming liquids F to the ejection head FH, which will be described later.

In the first embodiment, the color film forming liquid F exhibits a light absorption rate of 90 percent with respect to a laser beam B, which will be discussed later. The dispersion medium of the color film forming liquid F produces an evaporation heat of 2×10⁸ J/m³. However, the present invention is not restricted to these conditions.

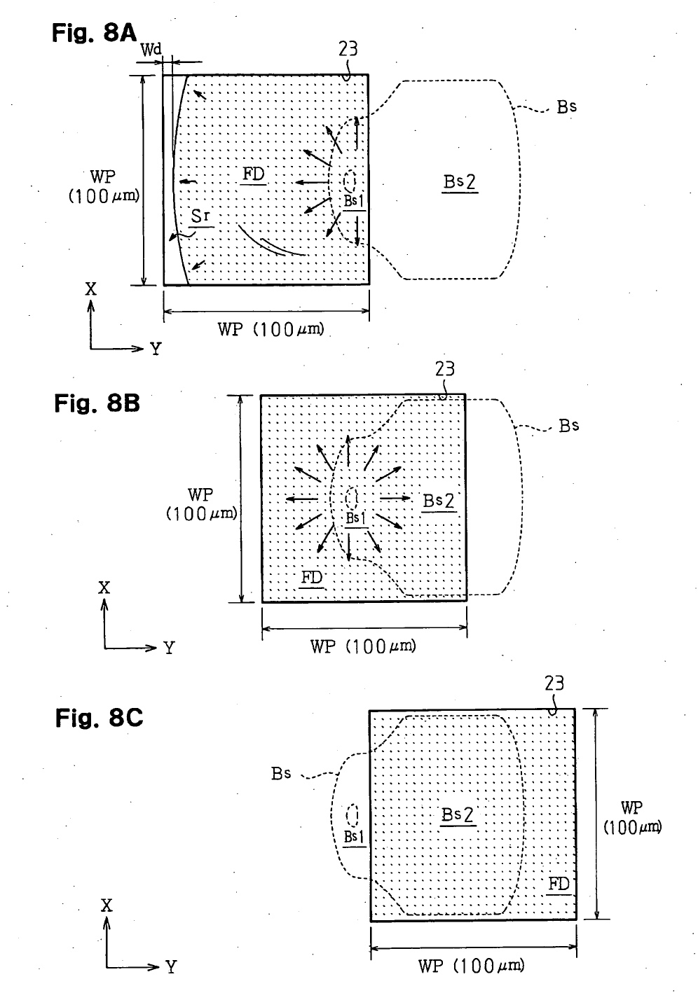

As shown in FIG. 4, a carriage 39 is secured to the bottom surface of the guide member 36. The carriage 39 has a non-illustrated linear movement mechanism provided in correspondence with a pair of upper and lower guide rails 38, which extend in direction X. The linear movement mechanism of the carriage 39 is formed by a threaded type linear movement mechanism having, for example, a threaded shaft (a drive shaft) extending along the guide rails 38 in direction Y and a ball nut engaged with the threaded shaft. The drive shaft of the linear movement mechanism is connected to an x-axis motor MX (see FIG. 8), which is a stepping motor. The x-axis motor MX rotates in a forward or reverse direction in response to a drive signal corresponding to a predetermined number of steps. This advances or retreats (moves) the carriage 39 along direction X by an amount corresponding to the number of the steps.

In the first embodiment, referring to FIG. 4, when the carriage 39 is located at a position closest to the support 35a (as indicated by the solid lines in FIG. 4), or when the carriage 39 is located at a foremost position in direction X, it is defined that the carriage 39 is arranged at a proceed position. When the carriage 39 is located at a position closest to the support 35b (as indicated by the double-dotted broken lines in FIG. 4), or when the carriage 39 is located at a rearmost position in direction X, it is defined that the carriage 39 is arranged at a return position.

As shown in FIG. 4, the liquid droplet ejection head FH is arranged below the carriage 39 and extends in direction X. The ejection head FH forms a liquid droplet ejecting portion of the three colors (red, green, and blue) corresponding to the color films 24R, 24G, 24B. FIG. 5 is a perspective view showing the ejection head FH with the bottom surface of the ejection head FH (i.e. the surface of the ejection head FH that is opposed to the substrate stage 33) facing upward. FIG. 6 is a cross-sectional view showing the interior of a main portion of the ejection head FH.

As shown in FIG. 5, a nozzle plate 41 is provided on the bottom surface of the ejection head FH. The bottom surface of the nozzle plate 41 (the nozzle surface 41a) includes 180 nozzle holes N that eject the microdroplets Fb, as will be later explained. The nozzle holes N extend through the nozzle plate 41 and are aligned in direction X and equally spaced. The pitch of the nozzle holes N is equal to the pitch of the color film forming areas 23 The nozzle holes N oppose the corresponding color film forming areas 23 when the color filter substrate 10 is (the color film forming areas 23 are) linearly reciprocated along direction Y. Each of the nozzle holes N extends perpendicular to the nozzle surface 41a and perpendicular to the surface of the color filter substrate 10 having the color film forming areas 23. The microdroplets Fb (see FIG. 6) ejected through the nozzle holes N thus travel along direction Z.

As shown in FIG. 6, cavities 42, or pressure chambers, are defined in the ejection head FH above the corresponding nozzle holes N direction Z. Each cavity 42 communicates with the tank 37 through a corresponding communication bore 43 and a supply line 44, which is provided commonly for the communication bores 43. The color film forming liquid F of the corresponding color is thus introduced from the tank 37 into each cavity 42. The cavity 42 then provides the color film forming liquid F to the associated nozzle hole N.

An oscillation plate 45 is arranged above the cavities 42. The oscillation plate 45 is formed by, for example, a polyphenylene sulfide (PPS) film the thickness of which is approximately 2 μm. The oscillation plate 45 is capable of oscillating in a vertical direction. Through such oscillation, oscillation plate 45 selectively increases and decreases the volume of each cavity 42. One hundred and eighty piezoelectric elements PZ are arranged above the oscillation plates 45 and in correspondence with the nozzle holes N. Each of the piezoelectric elements PZ receives a corresponding drive signal, which is a corresponding piezoelectric element drive signal COM1 (see FIG. 9). In response to the drive signal, the piezoelectric element PZ contracts and extends in the vertical direction, thus oscillating the oscillation plate 45 in the vertical direction.

Through such contraction and extension, the piezoelectric element PZ increases and then decreases the volume of the corresponding cavity 42. The color film forming liquid F is thus ejected from the corresponding nozzle hole N as the microdroplet Fb by an amount corresponding to the decrease of the volume of the cavity 42. The microdroplet Fb then reaches a position on the color film forming surface 21a and immediately below the nozzle hole N. In the first embodiment, referring to FIG. 6, in response to the corresponding piezoelectric element drive signal COM1, each of the piezoelectric elements PZ performs a single ejection cycle in which five microdroplets Fb are continuously ejected in not more than 70 μs and in a connecting manner. The total amount of the droplet FD is 50 pl. However, the present invention is not restricted to this.

In this embodiment, a position at which the droplet FD is received by the corresponding color film forming area 23 is defined as a target ejecting position Pa. With reference to FIG. 6, the target ejecting position Pa is located offset from a middle portion 23c of each color film forming area 23 in direction Y in accordance with a predetermined distance (an adjustment distance Ly1). Accordingly, a section free from the droplet FD (a dry section Sr) is formed not in a portion of the color film forming area 23 located forward in direction Y but in a portion of the color film forming area 23 located rearward in direction Y. The dry section Sr has a predetermined width (a dry width Wd).

As shown in FIG. 4, a laser head LH, which is energy beam radiating portion, is provided below the carriage 39 and forward from the ejection head FH in direction Y.

With reference to FIGS. 5 and 6, the bottom surface of the laser head LH includes 180 radiation ports 47, which are provided in correspondence with the nozzle holes N at positions forward from the nozzle holes N in direction Y.

As shown in FIG. 6, a semiconductor laser array LD having a plurality of semiconductor lasers L is provided in the laser head LH. The semiconductor lasers L are arranged in correspondence with the radiation ports 47. Each of the semiconductor lasers L receives a drive signal for driving the semiconductor laser L, which is a laser drive signal COM2 (see FIG. 9). In response to the drive signal, the semiconductor laser L radiates a laser beam B. In the first embodiment, the laser beam B is coherent light having a wavelength that causes evaporation of the dispersion medium of the droplet FD or converts the optical energy of the laser beam B into translational motion of the molecules forming the droplet FD.

In the laser head LH, a diffraction element 48 is provided near each of the semiconductor lasers L at a position corresponding to the corresponding radiation port 47. The diffraction element 48 is electrically or mechanically actuated and receives a drive signal for driving the diffraction element 48(a spot formation signal SB1, see FIG. 9). The diffraction element 48 thus performs a prescribed phase modulation on the laser beam B radiated by each semiconductor laser L.

That is, when the semiconductor laser L receives the laser drive signal COM2 and the diffraction element 48 receives the spot formation signal SB1, the laser beam B of the semiconductor laser L is subjected to the phase modulation by the diffraction element 48. This provides a prescribed laser beam cross section (a beam spot Bs) on the color film forming surface 21a.

When the beam spot Bs receives the corresponding droplet FD, which has reached the target ejecting position Pa and has been transported at the transport speed Vy in direction Y, the laser head H continuously radiates the laser beam B defining the beam spot Bs onto the droplet FD for a radiation time inversely proportional to the transport speed Vy pf the droplet FD.

In the first embodiment, referring to FIG. 6, the distance between the end of the beam spot Bs located rearmost in direction Y (closer to the target ejecting position Pa) and the end of the color film forming area 23 corresponding to the target ejecting position Pa located foremost in direction Y is defined as a radiation standby distance Ly2. The time needed for transporting the droplet FD from the target ejecting position Pa by a distance corresponding to the radiation standby distance Ly2 is defined as a standby time T.

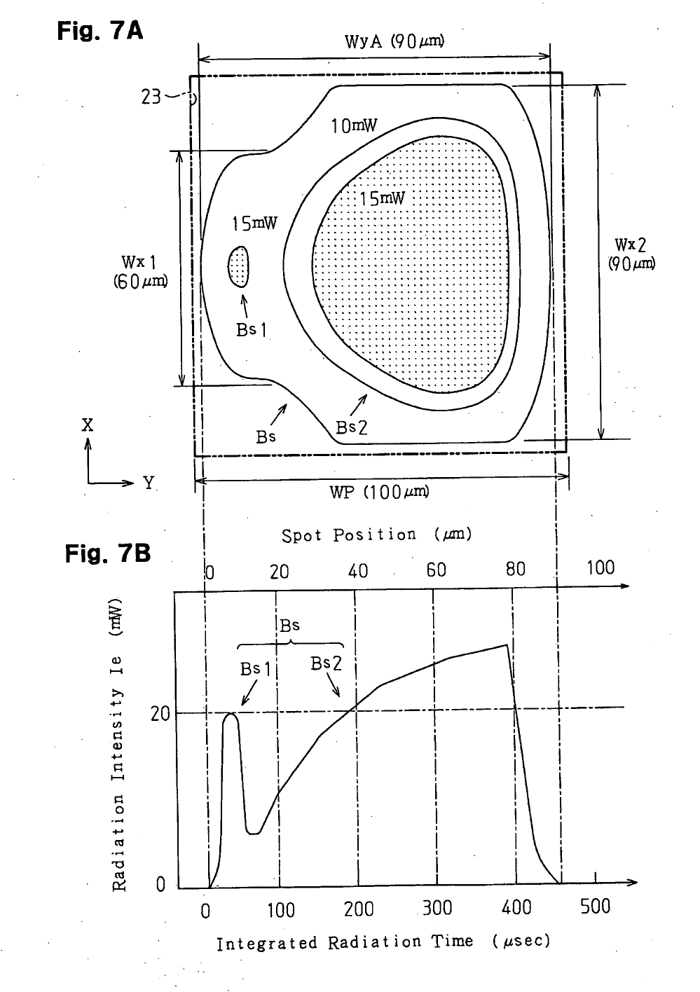

Next, the shape and the intensity distribution of the beam spot Bs of the first embodiment will be explained. In FIGS. 7A and 7B, the intensity distribution of the beam spot Bs is shown. In FIG. 7B, the upper abscissa axis corresponds to the position of the beam spot Bs (the spot position) in direction Y with respect to the end of the beam spot Bs located foremost in direction Y as a reference. The lower abscissa axis of the diagram corresponds to the time that elapses since entering of the droplet FD in the beam spot Bs (the integrated radiation time). The ordinate axis of the diagram corresponds to the intensity of the laser beam B (the radiation intensity Ie). FIGS. 8A to 8C are views showing the position of the beam spot Bs relative to the position of the corresponding color film forming area 23 (the corresponding droplet FD).

As shown in FIG. 7A, the beam spot Bs defines a blowing spot Bs1 and a drying spot Bs2. The blowing spot Bs1 is formed at a position rearward in direction Y. The drying spot Bs2 is located forward from the blowing spot Bs1 in direction Y. The blowing spot Bs1 and the drying spot Bs2 are connected to each other in direction Y as a continuous body. In this state, the total width of the blowing spot Bs1 and the drying spot Bs2 in direction Y (a scanning width WyA) is substantially equal to the pixel width WP.

The blowing spot Bs1 has a semielliptic shape that is elongated in direction X. The dimension of the blowing spot Bs1 in direction X (a blowing spot dimension W×1) is smaller than the pixel width WP. Referring to Fig- 7B, the width of the blowing spot Bs1 in direction Y corresponds to a value corresponding to the integrated radiation time of approximately 50 μs. The radiation intensity Ie of the blowing spot Bs1 exhibits a sharp peak in the vicinity of the middle portion of the blowing spot Bs1.

In the first embodiment, the maximum value of the radiation intensity of the blowing spot Bs1. (a first intensity) is set to 20 mW. However, the present invention is not restricted to this.

As shown in FIG. 8A, the droplet FD received by the color film forming area 23 is transported at the transport speed Vy (200 mm/s.) in direction Y and thus enters the blowing spot Bs1 (indicated by the corresponding broken lines in the drawing). Then, the laser beam B is radiated onto a portion of the droplet FD located foremost in direction Y at a position in the vicinity of a middle section of this portion of the droplet FD in direction X. The radiation of the laser beam B lasts for approximately 50 μs. The radiation intensity of the laser beam B rapidly rises and rapidly drops. As the droplet FD is continuously moved in direction Y, the laser beam B is scanned in the direction opposite to direction Y and relative to the droplet FD.

By radiating the blowing spot Bs1 defined by the laser beam B onto the droplet FD in the above-described manner, the optical energy of the laser beam B including a focally intense portion is supplied to the droplet FD in a shortened time (in the first embodiment, approximately 50 μs). Thus, the optical energy is converted into energy that excites the molecules only in a restricted portion of the droplet FD (a portion corresponding to the blowing spot Bs1). This produces oscillation energy for the dispersion medium and translational motion energy of the dispersion medium along the light incidence direction of the laser beam B (photons). In other words, the optical energy of the laser beam B evaporates the dispersion medium focally in the vicinity of the blowing spot Bs1 and moves the droplet FD in a direction coinciding with the light incidence direction of the laser beam B.

Thus, due to counteraction of the evaporating dispersion medium and the translational motion energy, a portion of the droplet FD in the vicinity of the blowing spot Bs1 is blown radially outward with respect to the blowing spot Bs1 (in a direction indicated by the corresponding arrows of FIG. 8A). This reduces the size of the dry section Sr.

The liquid FD is continuously transported relative to the blowing spot Bs1, as shown in FIG. 8B. Thus, by scanning the blowing spot Bs1 defined by the laser beam B in the direction opposite to direction Y, the liquid FD is filled in the entire dry section Sr while moving in the direction opposite to direction Y. The droplet FD thus entirely covers the color film forming area 23.

It is preferred that the radiation time and the radiation intensity Ie of the blowing spot Bs1 be modified as needed in accordance with the light absorption rate of the color film forming liquid F or the evaporation heat generated by the dispersion medium.

Referring to FIG. 7A, the drying spot Bs2 is larger than the blowing spot Bs1 and has an oval shape that is elongated in direction X. The dimension of the drying spot Bs2 in direction X (a drying spot dimension W×2) is substantially equal to the pixel width WP. With reference to FIG. 7B, the width of the drying spot Bs2 in direction Y is a value corresponding to the integrated radiation time of approximately 400 μs. The radiation intensity Ie of the drying spot Bs2 slowly becomes greater along direction Y.

In the first embodiment, the average of the radiation intensity Ie of the drying spot Bs (a second intensity) is set to 25 mW. However, the present invention is not restricted to this is As shown in FIG. 8B, after passing through the blowing spot Bs1, the droplet FD is continuously transported in direction Y and then enters the drying spot Bs2. In this state, the droplet FD is irradiated with the laser beam B along the entire dimension of the droplet FD in direction X. The radiation of the laser beam B lasts for approximately 400 μs. The radiation intensity Ie of the laser beam B slowly rises during the radiation. Such laser beam B is scanned onto the droplet FD, which is continuously transported in direction Y, in the direction opposite to direction Y and relative to the droplet FD.

That is, through the radiation of the drying spot Bs2 defined by the laser beam B onto the droplet FD, the optical energy that is slowly increasing is provided to a broader range of the droplet FD for a prolonged time. The optical energy of the laser beam B is thus converted into the energy for exciting molecules in the broader range of the droplet FD. The optical energy is converted into oscillation of the dispersion medium and random translational motion of the dispersion medium. In other words, the optical energy of the laser beam B is converted into evaporation of the dispersion medium in the broader range of the droplet FD.

The droplet FD further moves relative to the drying spot Bs2, referring to FIG. 8C, and the drying spot Bs2 defined by the laser beam B is scanned in the direction opposite to direction Y. This evaporates the dispersion medium of the droplet FD from the entire portion of the color film forming area 23, thus drying the droplet FD.

In this manner, the drying spot Bs defined by the laser beam B dries the droplet FD in a state filled in the color film forming area 23. Accordingly, the resulting color film 24 has a shape corresponding to that of the color film forming area 23.

In the first embodiment, the pixel width Wp, the blowing spot dimension W×1, the drying spot dimension W×2, and the scanning width WyB are set to 100 μm, 60 μm, 90 μm, and 90 μm, respectively. However, the present invention is not restricted to these set values. Further, in the laser head LH of this embodiment, the blowing spot Bs1 and the drying spot Bs2 are provided by the diffraction element 48. However, the blowing spot Bs1 and the drying spot Bs2 may be formed by an optical system having, for example, a mask and a diffraction grating.

The electric configuration of the liquid droplet ejection apparatus 30 will hereafter be explained with reference to FIG. 9.

As shown in FIG. 9, a controller 50 includes a control section 51 including, for example, a CPU, a RAM 52, and a ROM 53. The RAM 52 is defined by a DRAM and an SRAM and stores various data. The ROM 53 stores different control programs. The controller 50 also includes a drive signal generation circuit 54, a power supply circuit 55, and an oscillation circuit 56. The drive signal generation circuit 54 generates the piezoelectric element drive signal COM1. The power supply circuit 55 produces the laser drive signal COM2. The oscillation circuit 56 generates a clock signal CLK for synchronizing different signals. The controller 50 is defined by connecting the control section 51, the RAM 52, the ROM 53, the drive signal generation circuit 54, the power supply circuit 55, and the oscillation circuit 56 together through a bus (not shown).

An input device 61 is connected to the controller 50. The input device 61 includes manipulation switches such as a start switch and a stop switch. When each of the switches is manipulated, a manipulation signal is generated and input to the controller 50 (the control section 51). The input device 61 provides information about the color films 24, which are to be formed in the color filter substrate 10, to the controller 50 as a dot formation data Ia. In accordance with the dot formation data Ia and a control program (for example, a color filter manufacturing program) stored in the ROM 53, the controller 50 performs a transport procedure for transporting the color filter substrate 10 by moving the substrate stage 33 and a liquid ejection procedure by exciting selected ones of the piezoelectric elements PZ of the ejection head FH. Further, in accordance with the color filter manufacturing procedure, the controller 50 performs a drying procedure for drying the droplets FD by activating the semiconductor lasers L.

More specifically, the control section 51 performs a prescribed development procedure on the dot formation data Ia, which has been sent from the input device 61. The control section 51 thus produces bit map data BMD that indicates whether a droplet FD must be ejected onto each portion defined on a two-dimensional dot formation plane (the color film forming surface 21a). The control section 51 then stores the bit map data BMD in the RAM. In accordance with the value (0 or 1) of each bit of the bit map data BMD, the corresponding piezoelectric element PZ is selectively excited (ejection of a droplet FD is selectively permitted).

Also, the control section 51 subjects the dot formation data Ia, which has been sent from the input device 61, to a development procedure different from the development procedure performed on the bit map data BMD. The control section 51 thus produces waveform data of the piezoelectric element drive signal COM1 that satisfied dot forming conditions. The waveform data is output to the drive signal generation circuit 54 and then stored in a non-illustrated waveform memory. The drive signal generation circuit 54 converts the waveform data, which is digital, to an analog waveform signal. The analog waveform signal is then amplified, thus providing the piezoelectric element drive signal COM1.

The control section 51 then serially transfers the bit map data BMD to an ejection head driver circuit 67 (a shift register 67a), which will be described later, synchronously with the clock signal CLK of the oscillation circuit 56. In such transfer, data for each scanning cycle (corresponding to a single cycle of proceeding or returning of the substrate stage 33) is defined as ejection control data SI. Subsequently, the control section 51 produces the latch signal LAT for latching the serially transferred ejection control data SI for a single scanning cycle.

Further, synchronously with the clock signal CLK of the oscillation circuit 56, the control section 51 sends the piezoelectric drive signal COM1 to the ejection head driver circuit 67 (a switch circuit 67d) The control section 51 also provides a select signal SEL to the ejection head driver circuit 67 (the switch circuit 67d) for selecting the piezoelectric element drive signal COM1. The selected piezoelectric element drive signal COM1 is sent to the corresponding piezoelectric element PZ.

Referring to FIG. 9, an x-axis motor driver circuit 62 is connected to the controller 50. The controller 50 thus sends an x-axis motor drive signal to the x-axis motor driver circuit 62. In response to the x-axis motor drive signal, the x-axis motor driver circuit 62 rotates the x-axis motor MX, which operates to reciprocate the carriage 39, in a forward or reverse direction. For example, if the x-axis motor MX rotates in the forward direction, the carriage 39 moves in direction X. If the x-axis motor MX rotates in the reverse direction, the carriage 39 moves in the direction opposite to direction X.

A y-axis motor driver circuit 63 is connected to the controller 50. The controller 50 thus provides a y-axis motor drive signal to the y-axis motor driver circuit 63. In response to the y-axis motor drive signal, the y-axis motor driver circuit 63 rotates the y-axis motor MY, which operates to reciprocate the substrate stage 33, in a forward or reverse direction. For example, if the y-axis motor MY rotates in the forward direction, the substrate stage 33 moves in direction Y. If the y-axis motor MY rotates in the reverse direction, the substrate stage 33 moves in a direction opposite to direction Y.

A substrate detector 64 is connected to the controller 50. The substrate detector 64 detects an end of the color filter substrate 10. Through the substrate detector 64, the controller 50 calculates the position of the color filter substrate 10 that is (the color film forming areas 23 that are) moving immediately below the ejection head FH (the nozzle holes N).

An x-axis motor rotation detector 65 is connected to the controller 50. The x-axis motor rotation detector 65 sends a detection signal to the controller 50. In correspondence with the detection signal, the controller 50 determines the rotational direction and the rotation amount of the x-axis motor MX. The movement amount and the movement direction of the carriage 39 in direction X are thus correspondingly calculated.

A y-axis motor rotation detector 66 is connected to the controller 50. The y-axis motor rotation detector 66 sends a detection signal to the controller 50. In correspondence with the detection signal, the controller 50 determines the rotational direction and the rotation amount of the y-axis motor MY. The movement amount and the movement direction of the substrate stage 33 in direction Y are thus correspondingly calculated.

The ejection head driver circuit 67 and a laser head driver circuit 68 are connected to the controller 50.

The ejection head driver circuit 67 has the shift register 67a, a latch circuit 67b, a level shifter 67c, and the switch circuit 67d. The controller 50 sends the ejection control data SI to the shift register 67a synchronously with the clock signal CLK. The shift register 67a converts the ejection control data SI, which is serial data, to parallel data corresponding to the piezoelectric elements PZ. The obtained parallel ejection control data SI is latched by the latch circuit 67b synchronously with the latch signal LAT of the controller 50. The latched ejection control data SI is then sent to the level shifter 67c and a delay circuit 68a of the laser head driver circuit 68, which will be later described, sequentially at predetermined intervals synchronous with the clock signal CLK. The level shifter 67c raises the voltage of the latched ejection control data SI to the drive voltage of the switch circuit 67d, thus producing first open-close signals GS1 corresponding to the piezoelectric elements PZ.

The switch circuit 67d includes switch elements (not shown) corresponding to the piezoelectric elements PZ. The piezoelectric element drive signal COM1 corresponding to the select signal SEL is input to the input of the corresponding switch element. The output of the switch element is connected to the associated piezoelectric element PZ. Each switch element of the switch circuit 67d receives the corresponding first open-close signal GS1 from the level shifter 67c. In correspondence with the first open-close signal GS1, it is determined whether to provide the piezoelectric element drive signal COM1 to the corresponding piezoelectric element PZ.

In other words, in the liquid droplet ejection apparatus 30 of the first embodiment, the piezoelectric element drive signal COM1 is generated by the drive signal generation circuit 54 and sent to the corresponding piezoelectric element PZ. Sending of the piezoelectric element drive signal COM1 is controlled in correspondence with the ejection control data SI (the corresponding first open-close signal GS1) generated by the controller 50. That is, by providing the piezoelectric element drive signal COM1 to the piezoelectric element PZ, the corresponding switch element of which is held in a closed state, the droplet FD is ejected from the nozzle hole N corresponding to the piezoelectric element PZ.

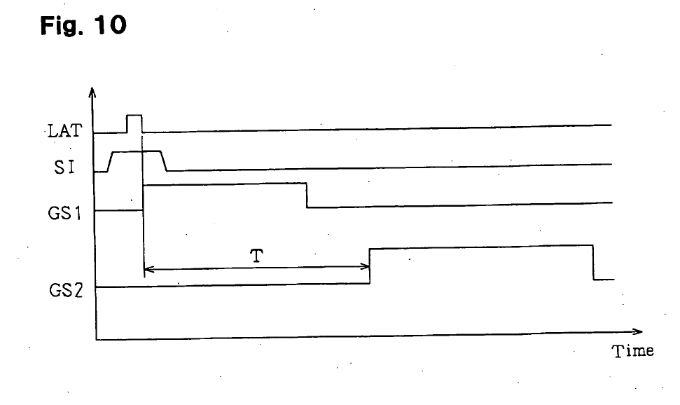

FIG. 10 is a timing chart representing the pulse waveforms of the latch signal LAT, the ejection control data SI, and the first open-close signal GS1.

As illustrated in FIG. 10, in response to the fall of the latch signal LAT, which has been provided to the ejection head driver circuit 67, the first open-close signal GS1 is generated in correspondence with the latched ejection control data SI. When the first open-close signal GS1 rises, the piezoelectric element drive signal COM1 is provided to the corresponding piezoelectric element PZ. The piezoelectric element PZ thus contracts and extends in correspondence with the piezoelectric element drive signal COM1. The droplet FD is thus ejected from the corresponding nozzle hole N and reaches the target ejection position Pa of the corresponding color film forming area 23. At this stage, the droplet FD forms the dry section Sr having the dry width Wd in a portion of the color film forming area 23 located rearward in direction Y. When the first open-close signal GS1 falls, ejection of the droplet FD is ended.

The laser head driver circuit 68 includes the delay circuit 68a, a diffraction element driver circuit 68b, and a switch circuit 68c.

The delay circuit 68a produces a pulse signal (a second open-close signal GS2) having a predetermined time width. The time width is determined by delaying the ejection control data SI that has been latched by the latch circuit 67b in accordance with the standby time T. The second open-close signal GS2 is then sent to the diffraction element driver circuit 68b and the switch circuit 68c.

In response to the second open-close signal GS2 of the delay circuit 68a, the diffraction element driver circuit 68b outputs the spot formation signal SB1 to the corresponding diffraction element 48. In response to the spot formation signal SB1, the diffraction element 48 is operated to form the blowing spot Bs1 and the drying spot Bs2.

The switch circuit 68c includes switch elements (not shown) corresponding to the semiconductor lasers L. The laser drive signal COM2, which has been produced by the power supply circuit 55, is sent to the input of each of the switch elements. The output of each switch element is connected to the corresponding semiconductor laser L. Each switch element of the switch circuit 68c receives the corresponding second open-close signal GS2 from the delay circuit 68a. In correspondence with the second open-close signal GS2, it is determined whether to provide the laser drive signal COM2 to the corresponding semiconductor laser L.

In other words, in the liquid droplet ejection apparatus 30 of the first embodiment, the laser drive signal COM2 is generated by the power supply circuit 55 and sent commonly to the corresponding semiconductor lasers L. Sending of the laser drive signal COM2 is controlled in correspondence with the ejection control data SI (the second open-close signal GS2), which has been produced by the controller 50 (the ejection head driver circuit 67). That is, in accordance with the ejection control data SI, the laser drive signal COM2 is provided to each of the semiconductor lasers L corresponding to the switch elements that are held in a closed state. This causes the semiconductor laser L to radiate the laser beam B, which defines the blowing spot Bs1 and the drying spot Bs2.

With reference to FIG. 10, after the standby time T has elapsed since inputting of the latch signal LAT to the ejection head driver circuit 67, the delay circuit 68a generates the second open-close signal GS2. The second open-close signal GS2 is sent to the diffraction element driver circuit 68b and the switch circuit 68c. In response to the rise of the second open-close signal GS2, the diffraction element driver circuit 68b outputs the spot formation signal SB1 to the corresponding diffraction element 48, thus operating the diffraction element 48 in correspondence with the spot formation signal SB1. On the other hand, in response to the rise of the second open-close signal GS2, the switch circuit 68c provides the laser drive signal COM2 to the corresponding semiconductor laser L, thus causing the semiconductor laser L to radiate the laser beam B.

That is, after the standby time T has elapsed, the beam spot Bs, which defines the blowing spot Bs1 and the drying spot Bs2, is generated. At this stage, the droplet FD, which has been ejected, enters the beam spot Bs. The blowing spot Bs1 and the drying spot Bs2 are then scanned onto the droplet FD in the direction opposite to direction Y and relative to the droplet FD. The droplet FD thus entirely covers the dry section Sr while maintained in a wet state. The droplet FD is then dried in a state filled in the entire portion of the color film forming area 23. This provides the color film 24 having a shape corresponding to that of the color film forming area 23. Later, the second open-close signal GS2 falls and thus sending of the laser drive signal COM2 is suspended. The drying procedure through the semiconductor laser array LD is thus ended.

Next, a method for forming the color filter substrate 10 (the color films 24) will be explained.

First, as illustrated in FIG. 4, the color filter substrate 10 is fixedly placed on the substrate stage 33, which is located at the proceed position. In this state, a side of the color filter substrate 10 located foremost in direction Y is arranged at a position rearward from the- guide member 36 in direction Y. The carriages 39 (the ejection head FH) is arranged in such a manner that the corresponding color film forming areas 23 pass immediately below the nozzle holes N when the color filter substrate 10 moves in direction Y.

The controller 50 then activates the y-axis motor MY, thus starting the substrate stage 33 to transport the color filter substrate 10 at the transport speed Vy in direction Y. When the substrate detector 64 detects the end of the color filter substrate 10 located foremost in direction Y, a detection signal is sent from the y-axis motor rotation detector 66 to the controller 50. The controller 50 thus determines whether the target ejecting positions Pa of the color film forming areas 23 of the first row have reached the positions immediately below the corresponding nozzle holes N.

Meanwhile, the controller 50 operates in accordance with the color filter manufacturing program. Specifically, the ejection control data SI, which has been formed based on the bit map data BMD stored in the RAM 52, and the piezoelectric element drive signal COM1, which has been generated by the drive signal generation circuit 54, are provided to the ejection head driver circuit 67. Also, the laser drive signal COM2, which has been produced by the power supply circuit 55, is provided to the laser head driver circuit 68. The control section 51 then stands by till it is time to input the latch signal LAT to the ejection head driver circuit 67.

When the target ejecting positions Pa of the color film forming areas 23 of the first row coincide with the positions immediately below the corresponding nozzle holes N, the controller 50 outputs the latch signal LAT to the ejection head driver circuit 67. In response to the latch signal LAT, the ejection head driver circuit 67 generates the first open-close signal GS1 in accordance with the ejection control data SI. The first open-close signal GS1 is then sent to the switch circuit 67d. This provides the piezoelectric element drive signal COM1 corresponding to the select signal SEL to each of the piezoelectric elements PZ corresponding to the switch elements that are held in a closed state. The droplets FD are thus simultaneously ejected from the corresponding nozzle holes N in correspondence with the piezoelectric element drive signal COM1. The droplets FD are thus simultaneously received by the corresponding color film forming areas 23, providing the dry sections Sr in the color film forming areas 23.

After the latch signal LAT has been received by the ejection head driver circuit 67, the laser head driver circuit 68 (the delay circuit 68a) starts generation of the second open-close signal GS2 in accordance with the ejection control data SI, which has been sent from the latch circuit 67b. The laser head driver circuit 68 then stands by till it is time to provide the second open-close signal GS2 to the diffraction element driver circuit 68b and the switch circuit 68c.

The laser head driver circuit 68 sends the second open-close signal GS2 to the diffraction element driver circuit 68b and the switch circuit 68c after the standby time T has elapsed since starting of the liquid ejection through the piezoelectric elements PZ, or outputting of the first open-close signal GS1 by the ejection head driver circuit 67.

The diffraction element driver circuit 68b then outputs the spot formation signal SB1 to the corresponding diffraction element 48, thus operating the diffraction element 48 in correspondence with the spot formation signal SB1. In response to the second open-close signal GS2, the switch circuit 68c provides the laser drive signal COM2 to each of the semiconductor lasers L corresponding to the switch elements that are held in a closed state. The laser beams B are thus simultaneously radiated by the corresponding semiconductor lasers L.

In this manner, each beam spot Bs, which defines the blowing spot Bs1 and the drying spot Bs2, is provided and the droplet FD, which has been received by the corresponding color film forming area 23, enters the beam spot Bs. Thus, through irradiation with the blowing spot Bs1 and the drying spot Bs2, the droplet FD is dried in a state filled in the entire color film forming area 23. This provides the color film 24 having a shape corresponding to the color film forming area 23.

The controller 50 continuously operates in the same manner as has been described for the first row of the color film forming areas 23. That is, the droplets FD are simultaneously ejected from the corresponding nozzle holes N when the target ejecting positions Pa of the color film forming areas 23 of a corresponding row coincide with the positions immediately below the nozzle holes N. After the standby time T has elapsed, the blowing spots Bs1 and the drying spots Bs2 are provided to the corresponding droplets FD and scanned relative to the droplets FD.

When the color films 24 are formed in all of the color film forming areas 23, the controller 50 operates the y-axis motor MY to return the substrate stage 33 (the color filter substrate 10) to the proceed position.

The first embodiment, which is constructed as above-described, has the following advantages.

(1) In the first embodiment, the blowing spot Bs1 is formed in the portion of each beam spot Bs located rearward in direction Y. The width of the blowing spot Bs1 in-direction Y is set to the value corresponding to the integrated radiation time of approximately 50 μs. The radiation intensity Ie of the blowing spot Bs1 exhibits a sharp peak in the vicinity of the middle portion- of the blowing spot Bs1. The droplet FD, which has been received by the corresponding color film forming area 23, enters the blowing spot Bs1 while moving at the transport speed Vy (20 mm/s.) in direction Y. At this stage, the laser beam B is radiated onto the vicinity of the middle portion of the droplet FD in direction X. Such radiation lasts for approximately 50 μs. The radiation intensity Ie of the laser beam B rapidly rises and rapidly drops.

The portion of the droplet FD in the vicinity of the blowing spot Bs1 is thus blown in a radial outward direction with respect to the blowing spot Bs1. This reduces the size of the dry section Sr of the color film forming area 23.

That is, through the radiation of the blowing spot Bs1 defined by the laser beam B the shape of the resulting color film 24 is adjusted with improved accuracy.

(2) In the first embodiment, the droplet FD is moved relative to the blowing spot Bs1. The blowing spot Bs1 defined by the laser beam B is thus scanned in the direction opposite to direction Y and relative to the droplet FD.

This further causes the droplet FD to flow in the direction opposite to direction Y, in such a manner that the droplet FD reliably spreads to cover the entire dry section Sr. The droplet FD thus has a shape corresponding to the color film forming area 23 when spreading of the droplet FD is completed. This provides the color film 24 having the shape corresponding to that of the color film forming area 23.

(3) In the first embodiment, the drying spot Bs2 is formed in the portion of the beam spot Bs located forward from the blowing spot Bs1 in direction Y. The drying spot Bs2 is larger than the blowing spot Bs1 and has an oval shape having a longer side extending in direction X. The dimension of the drying spot Bs2 in direction X is substantially equal to the pixel width WP. The width of the drying spot Bs2 in direction Y is set to the value corresponding to the integrated radiation time of approximately 400 μs. The radiation intensity Ie of the drying spot Bs2 slowly becomes greater along direction Y.

Thus, the drying spot Bs2 defined by the laser beam B is radiated onto the droplet FD along a substantially entire portion of the dimension of the droplet FD in direction X. The radiation of the laser beam B lasts for approximately 400 μs. The radiation intensity Ie of the laser beam B slowly increases during the radiation. In other words, through the radiation of the drying spot Bs2 defined by the laser beam B, a slowly increasing optical energy can be supplied to a wider range of the droplet FD for a prolonged time.

That is, drying of the droplet FD is started immediately after the droplet FD has passed through the blowing spot Bs1. The droplet FD is thus dried in the state filled in the color film forming area 23.

(4) In the first embodiment, the droplet FD is moved relative to the drying spot Bs2. That is, the drying spot Bs2 defined by the laser beam B is scanned in the direction opposite to direction Y and relative to the droplet FD.

Through such scanning of the drying spot Bs2, the droplet FD is entirely irradiated with the drying spot Bs2 having an increased uniformity, which is defined by the laser beam B. The droplet FD is thus dried with improved uniformity in a size corresponding to the size of the color film forming area 23. This provides the color film 24 having the shape corresponding to the shape of the color film forming area 23 with increased reliability.

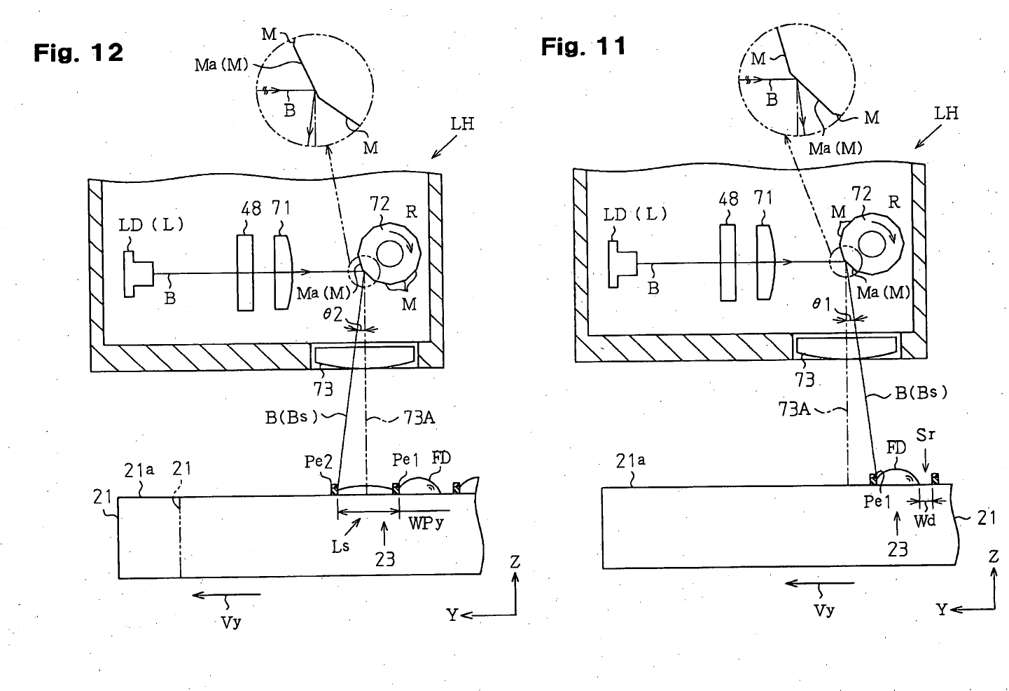

A second embodiment of the present invention will now be described with reference to FIGS. 11 to 15. In the second embodiment, the optical system of the laser head LH is modified from that of the first embodiment. The following description focuses on such modification.

As shown in FIG. 11, the laser head LH includes a cylindrical lens 71, a polygon mirror 72 forming energy beam scanning portion, and a scanning lens 73, in addition to the semiconductor laser array LD and the diffraction element 48 of the first embodiment.

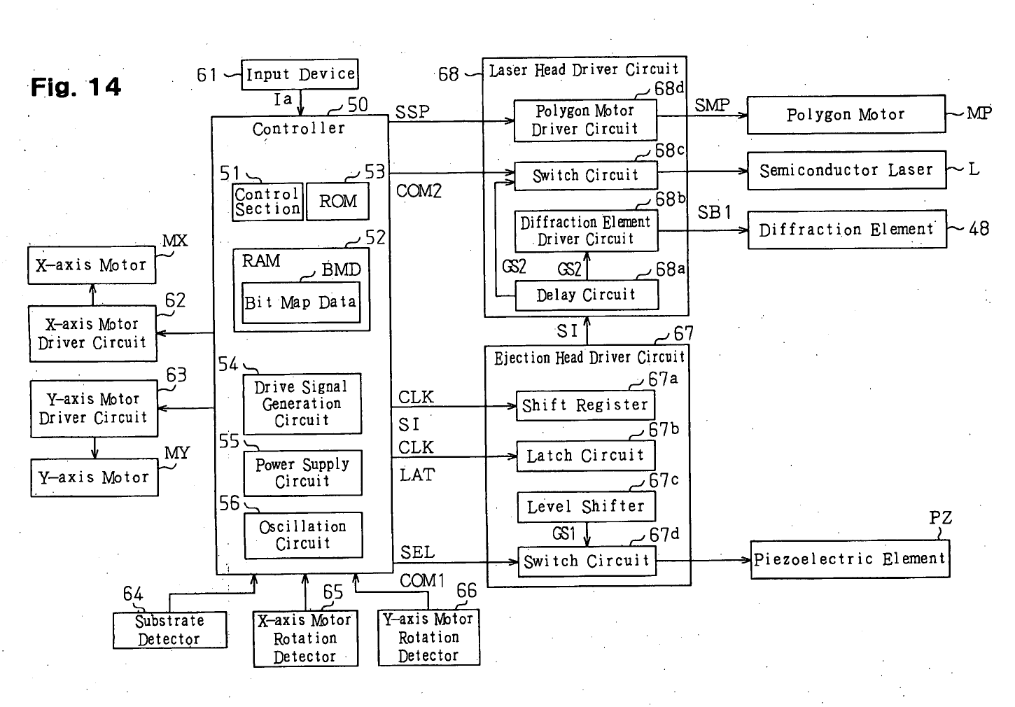

The cylindrical lens 71 has curvature only in direction Z. The cylindrical lens 71 performs “optical face tangle error correction” for the polygon mirror 72. The cylindrical lens 71 guides the laser beam B to the polygon mirror 72. The polygon mirror 72 has thirty-six reflective surfaces M, which define a regular triacontakaihexagon (a regular thirty-six-sided polygon) as a whole. The reflective surfaces M are rotated by a polygon motor (see FIG. 14) in a direction indicated by arrow R of FIG. 11. Every time the rotational angle θp of the polygon mirror 72 is advanced at 10 degrees in direction R, the, reflective surface M that receives the laser beam B is switched from a preceding reflective surface M to a following reflective surface M. The scanning lens 73 is defined by an f-theta lens that maintains the scanning speed of the laser beam B on the color film forming surface 21a to a constant level.

In FIG. 11, the laser beam B from the cylindrical lens 71 is received by the end of the reflective surface M (Ma) of the polygon mirror 72 located forward in direction R. The deflection angle of the laser beam B which is reflected and deflected by the polygon mirror 72, is a deflection angle θ1 (in the second embodiment, five degrees). In this embodiment, in the state of FIG. 11, it is defined the rotational angle θp of the polygon mirror 72 is zero degrees.

When the rotational angle θp of the polygon mirror 72 is zero degrees and the laser beam B that has been subjected to phase modulation by the diffraction element 48 is guided to the cylindrical lens 71, the cylindrical lens 71 adjusts the optical axis of the laser beam B with respect to a direction perpendicular to the sheet surface of FIG. 11. The laser beam B is then sent to the polygon mirror 72. The laser beam B is thus reflected and deflected by the reflective surface Ma in the direction defining the deflection angle θ1 with respect to the optical axis 73A of the scanning lens 73. The laser beam B is then sent to the color film forming surface 21a through the scanning lens 73.

In the second embodiment, the radiating position of the laser beam B on the color film forming surface 21a when the rotational angle θp is zero degrees is referred to as a radiation start position Pe1. The radiation start position Pe1 coincides with the radiation start position of the laser beam B defining the beam spot Bs of the first embodiment. In other words, the radiation start position Pe1 coincides with the position of the droplet FD, which has been received by the color film forming area 23, after the standby time T has elapsed since starting of the liquid ejection.

Thus, as illustrated in FIG. 11, when the rotational angle θp of the polygon mirror 72 is zero degrees and the droplet FD reaches the radiation start position Pe1, the droplet FD is irradiated with the laser beam 3 that has been reflected and deflected by the reflective surface Ma of the polygon mirror 72.

Then, referring to FIG. 12, the polygon mirror 72 is rotated in direction R till the rotational angle θp becomes approximately 10 degrees. In this state, the polygon mirror 72 deflects and reflects the laser beam B at the end of the reflective surface Ma located rearward in direction R in a direction defining a deflection angle θ2 (in the second embodiment, −5 degrees) with respect to the optical axis 73A. The laser beam B is thus guided to the color film forming surface 21a through the scanning lens 73.

In the second embodiment, the radiating position of the laser beam B on the color film forming surface 21a when the rotational angle θp of the polygon mirror 72 is ten degrees is referred to as a radiation end position Pe2. The area between the radiation start position Pe1 and the radiation end position Pe2 is defined as a scanning zone Ls. The width of the scanning zone Ls in direction Y (a scanning width WPy) is set to a value equal to the pitch of the color film forming areas 23 in direction Y.

In other words, through operation of the polygon mirror 72, the laser head LH scans (moves) the laser beam B (the beam spot Bs) throughout the corresponding one of the color film forming areas 23 (from the radiation start position pe1 to the radiation end position Pe2).

Further, in this embodiment, the rotational speed of the polygon motor MP is set to a level at which a single scanning cycle of the laser beam B corresponds to a single movement cycle of the color film forming area 23, which moves from the radiation start position Pe1 to the radiation end position Pe2. Therefore, the laser beam B is radiated onto the droplet FD, which proceeds in the scanning zone Ls, while maintained stationary relative to the droplet FD.

In response to the spot formation signal SB1, the diffraction element 48 of this embodiment performs a prescribed dynamic phase modulation on the laser beam B in accordance with a cycle corresponding to the scanning cycle (scanning width WPy/scanning speed Vy) of the laser beam B. Through such phase modulation by the diffraction element 48 of the second embodiment, the beam spot Bs of the first embodiment is scanned in the direction opposite to direction Y and relative to the corresponding color film forming area 23 (the droplet FD), in such a manner that the blowing spot Bs1 precedes the drying spot Bs2.

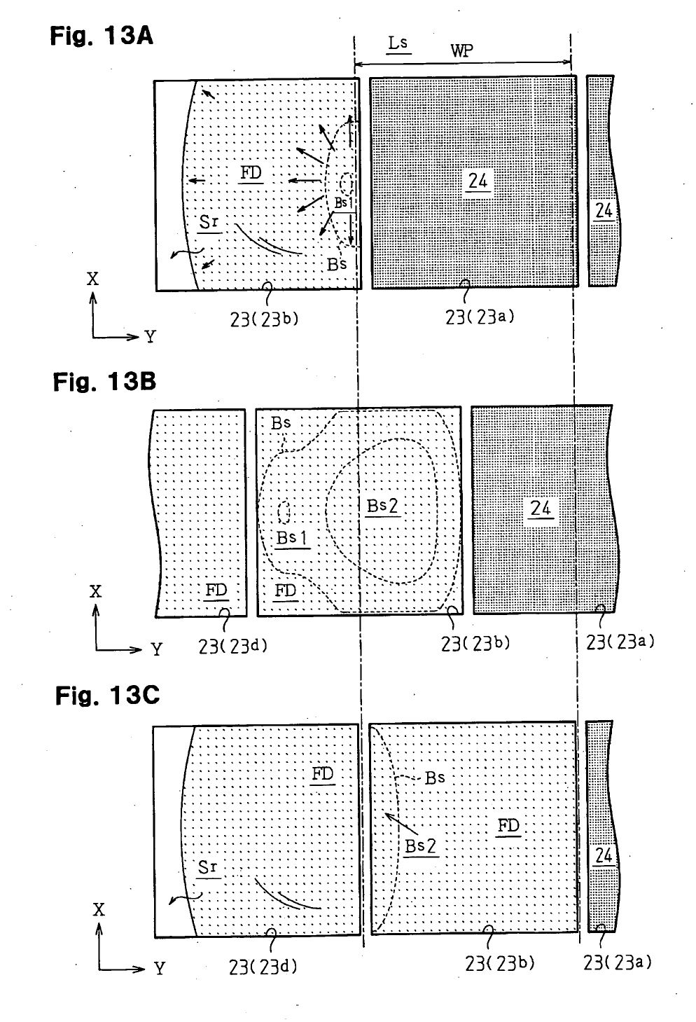

More specifically, as illustrated in FIG. 13A, the end of the preceding color film forming area 23 (23a) located foremost in direction Y separates from the scanning zone Ls (indicated by the single-dotted broken lines in the drawing). At this stage, the end of the following color film forming area 23 (23b) located foremost in direction Y enters the scanning zone Ls. Thus, the laser beam B maintained stationary relative to the color film forming area 23b is radiated onto the following color film forming area 23b and scanned by the polygon mirror 72. In this state, as indicated by the broken line of FIG. 13A, the foremost end of the color film forming area 23b is irradiated with the blowing spot Bs1 defined by the laser beam B, which has been described for the first embodiment. As the color film forming area 23b continuously proceeds in the scanning zone Ls, the laser beam B, which is dynamically phase-modulated, is continuously radiated onto the color film forming area 23b. The blowing spot Bs1 is thus scanned in the direction opposite to direction Y and relative to the color film forming area 23b.

By the time the color film forming area 23b reaches a substantial middle portion of the scanning zone Ls, the blowing spot Bs1 has moved throughout the color film forming area 23b to the end of the color film forming area 23b located rearmost in direction Y, as indicated by the corresponding broken lines of FIG. 13B. In this state, the drying spot Bs2 defined by the laser beam B, which has been explained for the first embodiment, is radiated onto the portion of the color film forming area 23b located forward in direction Y. As the color film forming area 23b continuously proceeds in the scanning zone Ls, the laser beam B defining the beam spot Bs, which is dynamically phase-modulated, is continuously radiated onto the color film forming area 23b. The drying spot Bs2 defined by the laser beam B is thus scanned in the direction opposite to direction Y and relative to the color film forming area 23b.

By the time the end of the color film forming area 23b foremost in direction Y reaches a position close to the end of the scanning zone Ls foremost in direction Y, the drying spot Bs2 defined by the laser beam B has moved throughout the color film forming area 23b to the end of the color film forming area 23b rearmost in direction Y, as indicated by the corresponding broken line in FIG. 13C.

When the color film forming area 23b separates from the scanning zone Ls, the following color film forming area 23d enters the scanning zone Ls. The color film forming area 23d is thus irradiated with the laser beam B defining the beam spot Bs in the same manner as has been described for the color film forming area 23b.

That is, when proceeding in the scanning zone Ls, each color film forming area 23 is irradiated with the beam spot Bs which is dynamically phase-modulated in accordance with the cycle corresponding to the scanning cycle of the laser beam B. Thus, the blowing spot Bs1 and the drying spot Bs2, which are defined by the laser beam B, are sequentially radiated onto the color film forming area 23 in the direction opposite direction Y and relative to the color film forming area 23. Therefore, through such scanning in the scanning zone Ls, the droplet FD is spread to cover the entire portion of the dry section Sr and dried in a state filled in the entire color film forming area 23.

The electric configuration of the liquid droplet ejection apparatus 30, which is constructed as above-described, will hereafter be explained with reference to FIG. 14.

The laser head driver circuit 68 includes a polygon motor driver circuit 68d. In response to a polygon motor start signal SSP of the controller 50, the polygon motor driver circuit 68d generates a polygon motor control signal SMP. The polygon motor control signal SMP is then output to the polygon motor MP, thus rotating the polygon motor MP.

In correspondence with the detection signal of the substrate detector 64, the controller 50 outputs the polygon motor start signal SSP for starting the polygon motor MP. Specifically, when the ends of the color film forming areas 23 of the first row that are located foremost in direction Y coincide with the radiation start positions Pe1, the controller 50 outputs the polygon motor start signal SSP to the laser head driver circuit 68 at a predetermined timing, in such a manner that the rotational angle θp of the polygon mirror 72 becomes zero degrees.

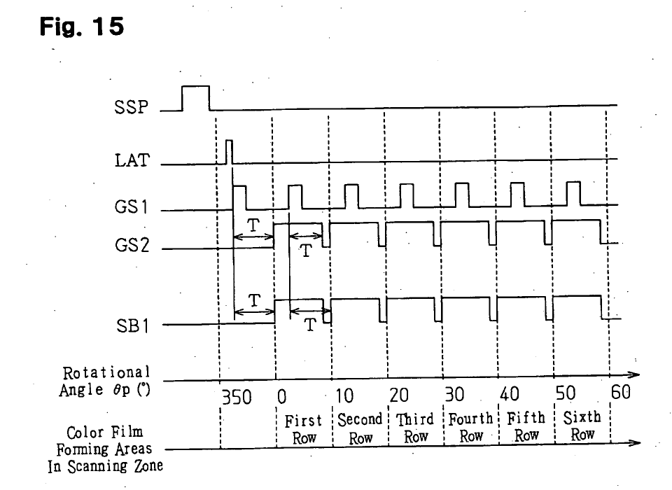

FIG. 15 represents pulse waveforms of the latch signal LAT, the first open-close signal GS1, the second open-close signal GS2, and the spot formation signal SB1, the rotational angle θp, and the numbers of the rows of the color film forming areas 23 that are located in the scanning zone Ls.

As the color filter substrate 10 is transported at the transport speed Vy in direction Y in a state mounted on the substrate stage 33, the substrate detector 64 detects the end of the color filter substrate 10 located foremost in direction Y. In response to such detection, referring to FIG. 15, the controller 50 generates the polygon motor start signal SSP at a predetermined timing. When the polygon motor start signal SSP rises; the polygon-motor driver circuit 68d produces the polygon motor control signal SMP, thus starting rotation of the polygon mirror 72 in direction R.

Through such operation, the operational angle θp of the polygon mirror 72 becomes zero degrees when the end of each color film forming area 23 of the first row coincides with the corresponding radiation start position Pe1.

Like the first embodiment, when the target ejecting position Pa of each color film forming area 23 of the first row reaches the position immediately below the corresponding nozzle hole N, the latch signal LAT falls and the first open-close signal GS1 is generated. The droplets FD are thus simultaneously ejected through the corresponding nozzle holes N. The droplets FD are simultaneously received by the corresponding color film forming areas 23 of the first row.

After the standby time T has elapsed since the rise of the first open-close signal GS1 (starting of the liquid ejection onto the color film forming areas 23 of the first row), the end of each color film forming area 23 of the first row located foremost in direction Y enters the scanning zone Ls. At this point, the laser head driver circuit 68 generates the second open-close signal GS2. When the second open-close signal GS2 rises, the laser beams B, which define the beam spots Bs (the blowing spots Bs1), are simultaneously radiated through the corresponding radiation ports 47.

In this state, as shown in FIG. 15, the rotational angle ηp of the polygon mirror 72 is zero degrees. The blowing spot Bs1 defined by the laser beam B is radiated onto the droplet FD located at the radiating start position Pe1. As the droplets FD continuously proceed in the scanning zone Ls, the laser beams B are continuously radiated onto only the droplets FD in the corresponding color film forming areas 23. That is, the blowing spot Bs1 and the drying spot Bs2, which are defined by the laser beam B, are scanned relative to the corresponding droplet FD.

Then, the second open-close signal GS2 falls and radiation of the laser beams B from the semiconductor lasers L is suspended. The drying procedure of the droplets FD of the first row is thus ended.

Subsequently, after the liquid ejection onto the color film forming areas 23 of the second row has started and then the standby time T has elapsed, the color film forming areas 23 of the first row separate from the scanning zone Ls while the ends of the color film forming areas 23 of the second row located foremost in direction Y enter the scanning zone Ls. The second open-close signal GS2 is thus generated by the laser head driver circuit 68. In response to the rise of the second open-close signal GS2, the blowing spots Bs1 defined by the laser beams B are simultaneously radiated through the corresponding radiation ports 47.

In this state, referring to FIG. 15, the rotational angle θp of the polygon mirror 72 is zero degrees. Thus, the blowing spot Bs1 defined by the laser beam B is radiated onto the corresponding droplet FD of the second row located at the radiation start position Pe1.

Afterwards, the color film forming areas 23 of the following rows, which contain the corresponding droplets FD, successively enter the scanning zone Ls. In the scanning zone Ls, each of the droplets FD is irradiated with the blowing spot Bs1 and the drying spot Bs2, which are scanned in the direction opposite to direction Y and relative to the droplet FD. This provides the color films 24, each of which has the shape substantially identical with that of the color film forming area 23.

Also in the second embodiment, the size of the dry section Sr is decreased by blowing the portion of the droplet FD in the vicinity of the blowing spot Bs1, like the first embodiment. This improves the accuracy for adjusting the shapes of the color films 24R, 24G, 24B. Further, the drying spot Bs2 is scanned onto the droplet FD relative to the droplet FD. The droplet FD is thus uniformly dried in a size corresponding to the size of each color film forming area 23. Accordingly, the color films 24 shaped in correspondence with the color film forming areas 23 are formed with improved reliability.

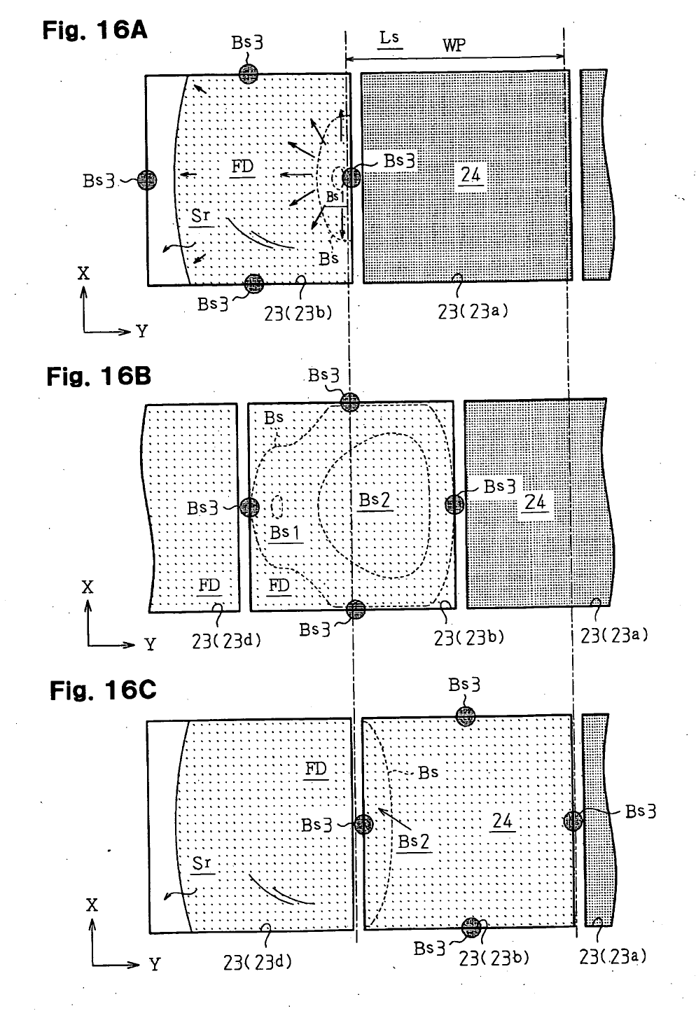

A third embodiment of the present invention will hereafter be described with reference to FIGS. 16A, 16B, 16C. The third embodiment is different from the second embodiment in terms of beam spots. The following description focuses on the difference between the two embodiments.

As illustrated in FIG. 16A, pinning spots Bs3 are each formed at a middle portion of the corresponding side of each color film forming area 23 in the scanning zone Ls. Each of the pinning spots Bs3 has a diameter smaller than the diameter of the blowing spot Bs1. The pinning spots Bs3 dry and fix the droplet FD to the color film forming area 23. In other words, each pinning spot Bs3 prevents the droplet FD from moving outwardly beyond the radiating position of the pinning spot Bs3.

Each pinning spot Bs3 defined by the laser beam B is radiated onto the droplet FD while maintained stationary relative to the droplet FD through scanning by the polygon mirror 72. The radiation of the pinning spots Bs3 is maintained while the blowing spot Bs1 and the drying spot Bs2 defined by the laser beam B are scanned in the direction opposite to direction Y and relative to the droplet FD. In other words, as illustrated in FIGS. 16B and 16C, the pinning spots Bs3 each defined by the laser beam B are constantly radiated onto the middle portions of the corresponding four sides of the color film forming area 23, which is moving in the scanning zone Ls.

This allows each pinning spot Bs3 to suppress excessive movement of the droplet FD caused by the blowing spot Bs1. The droplet FD is thus contained (pinned) in the corresponding color film forming area 23.

In the third embodiment, by providing the pinning spots Bs3 maintained stationary relative to the color film forming area 23, the shape of the resulting color film 24 is adjusted with further improved accuracy.

The illustrated embodiments may be modified as follows.

In each of the illustrated embodiments, the blowing spot Bs1 has a substantially oval shape. However, the shape of the blowing spot Bs1 may be, for example, a crossed shape. That is, the blowing spot Bs1 may be shaped in any suitable manner as long as the blowing spot Bs1 can blow the liquid FD in a desired direction.

In each of the illustrated embodiments, the blowing spot Bs1 is radiated in the direction opposite to direction Z. However, the blowing spot Bs1 may be radiated in a direction that includes an element corresponding to the direction in which the droplet FD is blown (the direction opposite to direction Y). This efficiently converts the optical energy of the blowing spot Bs1 to the translational motion of the molecules forming the droplet FD.

In each of the illustrated embodiments, the dry section Sr is provided in the portion of each color film forming area 23 located rearward in direction Y. However, the dry section Sr may be located at any position in the color film forming area 23. In this case, the blowing spot Bs1 is preferably scanned isotropically outward from the middle portion of the color film forming area 23.

In the illustrated embodiments, the blowing spot Bs1 or the drying spot Bs2 or the pinning spots Bs3 are formed by the diffraction element 48, which is electrically or mechanically activated. However, the diffraction element 48 may be replaced by a diffraction grating, a mask, or a branching element. That is, as long as the blowing spot Bs1, the drying spot Bs2, or the pinning spots Bs3 can be provided to the droplet FD, any suitable optical system may be employed for forming these spots.

In each of the illustrated embodiments, each color film forming area 23 has a substantially square shape. However, the color film forming area 23 may have any other suitable shape, such as an oval shape or a polygonal shape. If the shape of the color film forming area 23 is modified, it is preferred that the shapes and the scanning directions of the blowing spot Bs1 and the drying spot Bs2 (and the pinning spots Bs3) be changed in correspondence with such modification.

In each of the illustrated embodiments, the energy beam is embodied as the laser beam B. However, the energy beam may be modified to, for example, incoherent light, an ion beam, or plasma light. Any other suitable energy beam may be employed as long as the energy beam is capable of blowing and drying the droplets FD in the corresponding color film forming areas 23.

In the second embodiment, the optical scanning system of the laser beam B is defined by the polygon mirror 72. However, the optical scanning system may be formed by, for example, a galvanometer mirror.

In the third embodiment, the pinning spots Bs3 are maintained stationary relative to the droplet FD. However, the pinning spots Bs3 may be scanned in a moving manner relative to the scanning direction of the blowing spot Bs1, or the flowing direction of the droplet FD. Alternatively, each of the pinning spots Bs3 may have a shape covering the entire outer circumference of the color film forming area 23.

In the third embodiment, the wall 22 (the liquid-repelling layer 22b), which is provided for each of the color film forming areas 23, may be omitted. In this case, the pinning spots Bs3 suppress excessive spreading of each droplet FD, thus adjusting the outline of the droplet FD to a predetermined shape. This configuration makes it unnecessary to perform the step for providing the wall 22 (the liquid repelling layer 22b). The productivity for forming the color films 24R, 24G, 24B is thus improved.

In each of the illustrated embodiments, the single ejection head FH and the single laser head LH are arranged in the liquid droplet ejection apparatus 30 and aligned in direction Y. However, multiple ejection heads FH and multiple laser heads LH may be provided along direction Y. In this case, a film having a predetermined thickness can be obtained through a single scanning cycle.

In each of the illustrated embodiments, the energy beam radiating portion is defined by the semiconductor laser L. However, the semiconductor laser L may be replaced by, for example, a carbon dioxide gas laser or a YAG laser. That is, any other suitable laser may be employed as long as the laser beam radiated by the laser has a wavelength that causes the droplets FD to flow and dries the droplets FD.

In each of the illustrated embodiments, the semiconductor lasers L are provided in the quantity equal to the quantity of the nozzle holes N. However, an optical system including a single laser light source may be employed. In this case, a single laser beam B radiated by the laser light source is branched into 16 rays by a branching element such as a diffraction element.

In each of the illustrated embodiments, the liquid droplet ejection apparatus 30 is used for forming the color films 24 on the color filter substrate 10. However, for example, an insulating film or a metal wiring pattern may be formed by the droplets FD, which are ejected by the liquid droplet ejection apparatus 30. Also in these cases, the shape of the insulating film or the metal wiring pattern can be adjusted with improved accuracy, like the illustrated embodiments. If it is necessary to bake the material of the insulating film or the metal wiring, a spot defined by the laser beam B should be radiated onto the material, following radiation of the drying spot Bs2 defined by the laser beam B of the illustrated embodiments. The spot for baking the material has a third radiation intensity that is greater than the radiation intensity Ie of the drying spot Bs2.

In each of the illustrated embodiments, the electro-optic device is embodied as the liquid crystal display 1. The multiple color films 24 are formed in the liquid crystal display 1 in accordance with a certain pattern. However, the electro-optic device formed according to the present invention may be an electroluminescence display including light emission elements that are provided in accordance with a certain pattern. In this case, the droplet FD contains material for forming the light emission elements. The droplet FD is ejected onto a light emission element forming area, thus providing the corresponding light emission element. Also in this case, the shape of each light emission element is adjusted with enhanced accuracy. The productivity for manufacturing the electroluminescence display is thus increased.

In each of the illustrated embodiments, the electro-optic device is embodied as the liquid crystal display 1, which includes the multiple color films 24 that are formed in accordance with a certain pattern. However, the electro-optic device formed according to the present invention may be a display having a field effect type device (an FED or an SED), in which an insulating film or a metal wiring is provided in accordance with a certain pattern. The field effect type device has a flat electron emission element and emits light from a fluorescent substance using electrons emitted by the electron emission element.

The present examples and embodiments are to be considered as illustrative and not restrictive and the invention is not to be limited to the details given herein, but may be modified within the scope and equivalence of the appended claims.

What is claimed is:

1. A liquid droplet ejection apparatus comprising:
a liquid droplet ejecting portion that ejects a liquid droplet containing a structure forming material onto a structure forming area defined on a target; and
an energy beam radiating portion that radiates an energy beam having a predetermined intensity onto at least a portion of the droplet on the structure forming area;
wherein the predetermined intensity is set to a value that permits the droplet on the structure forming area to spread wet on the structure forming area.

2. The apparatus according to claim 1, wherein the energy beam radiating portion scans the energy beam in a direction in which the droplet is desired to move when spreading.

3. The apparatus according to claim 1, wherein the energy beam radiating portion radiates the energy beam in a manner extending in a direction in which the droplet is desired to move when spreading.

4. The apparatus according to claim 1, wherein the energy beam is a light.

5. The apparatus according to claim 1, wherein the energy beam is a coherent light.

6. The apparatus according to claim 1, wherein:
the predetermined intensity is a first predetermined intensity; and
the energy beam radiating portion further radiates an energy beam having a second predetermined intensity higher than the first predetermined intensity onto the droplet that has spread wet on the structure forming area through radiation of the energy beam having the first predetermined intensity, thereby drying the droplet.

7. The apparatus according to claim 6, wherein the energy beam radiating portion further radiates an energy beam having a third predetermined intensity higher than the second predetermined intensity onto the droplet that has been dried through radiation of the energy beam having the second predetermined intensity, thereby baking the droplet.

8. The apparatus according to claim 1 further comprising an energy beam scanning portion that scans the energy beam in such a manner that a beam spot of the energy beam is maintained stationary relative to the droplet in the structure forming area.

9. The apparatus according to claim 1, wherein the energy beam radiating portion further radiates an energy beam onto an area surrounding the structure forming area, thereby preventing the droplet in the structure forming area from spreading wet beyond the structure forming area.

10. A method for forming a prescribed structure on a target, the method comprising:
ejecting a liquid containing a structure forming material onto the target;
drying the liquid on the target to form the structure; and
radiating an energy beam having a predetermined intensity onto at least a portion of the liquid on the target before or when drying the liquid on the target;
wherein the predetermined intensity is set to a value that permits the liquid on the target to spread wet on the target.

11. The method according to claim 10, wherein radiation of the energy beam having the predetermined intensity is performed before the droplet is dried on the target.

12. The method according to claim 10, wherein:
the predetermined intensity is a first intensity; and
drying of the liquid on the target includes radiation of an energy beam having a second predetermined intensity higher than the first predetermined intensity onto the liquid that has spread wet on the target through radiation of the energy beam having the first predetermined intensity.

13. A method for manufacturing an electro-optic device including a substrate in which a color film is provided, the method comprising forming the color film on the substrate, such formation of the color film includes:
ejecting a liquid droplet containing a color film forming material onto a color film forming area defined on the substrate;
drying the droplet on the color film forming area; and
radiating an energy beam having a predetermined intensity onto at leas t a portion of the droplet on the color film forming area before or when drying the droplet on the color film forming area;
wherein the predetermined intensity is set to a value that permits the droplet on the color film forming area to spread wet on the color film forming area.

14. A method for manufacturing an electro-optic device having a substrate in which a light emission element is provided, the method comprising forming the light emission element on the substrate, such formation of the light emission element includes:
ejecting a liquid droplet containing a light emission element forming material onto a light emission element forming area defined on the substrate;
drying the droplet on the light emission element forming area; and
radiating an energy beam having a predetermined intensity onto at least a portion of the droplet on the light emission element forming area before or when drying the droplet on the light emission element forming area;
wherein the predetermined intensity is set to a value that permits the droplet on the light emission element forming area to spread wet on the light-emission element forming area.
